(19) United States
(12) Patent Application Publication
(10) Pub. No.: US 2026/0333581 A1
(43) Pub. Date: Oct. 22, 2026

(54) ELECTRONIC ASSEMBLY AND PRINTED CIRCUIT BOARD

(71) Applicant: VIA Technologies, Inc., New Taipei City (TW)

(72) Inventors: Nai-Shung Chang, New Taipei City (TW); Chang-Li Tan, New Taipei City (TW); Chun-Yen Kang, New Taipei City (TW); Yun-Han Chen, New Taipei City (TW)

(73) Assignee: VIA Technologies, Inc., New Taipei City (TW)

(21) Appl. No.: 19/383,781

(22) Filed: Nov. 10, 2025

Related U.S. Application Data
(60) Provisional application No. 63/790,672, filed on Apr. 17, 2025.

(30) Foreign Application Priority Data
Sep. 11, 2025 (TW) 114134872

(51) Int. Cl. H05K 1/11

(52) U.S. Cl. CPC H05K 1/113; H05K 2201/093; H05K 2201/094; H05K 2201/09409; H05K 2201/09609; H05K 2201/09618; H05K 2201/09636; H05K 2201/10522; H05K 2201/10545

(57) ABSTRACT

An electronic assembly includes a printed circuit board having a first surface, a second surface opposite to the first surface, first conductive pads arranged on the first surface, and second conductive pads arranged on the second surface. The first conductive pads include first signal pads, a first signal adjustment pad, and a first ground pad. The second conductive pads include second signal pads and a second signal internal pad. Orthographic projections of the first ground pad and the second signal internal pad on the first surface are overlapped with each other. The second signal internal pad is electrically connected to the first signal adjustment pad. The first ground pad is electrically connected to a ground plane in the printed circuit board. The electronic assembly further includes a first electronic package electrically connected to the first conductive pads and a second electronic package electrically connected to the second conductive pads.

### CROSS-REFERENCE TO RELATED APPLICATION

This application claims the priority benefit of U.S. Provisional Application No. 63/790,672, filed on Apr. 17, 2025 and Taiwan Application No. 114134872, filed on Sep. 11, 2025. The entirety of each of the above-mentioned patent applications is hereby incorporated by reference herein and made a part of this specification.

### BACKGROUND OF THE INVENTION

### Field of the Invention

The invention relates to an electronic assembly, and more particularly to an electronic assembly, wherein a printed circuit board thereof is used for mounting an electronic package.

### Description of Related Art

A printed circuit board (PCB) is a common platform for mounting electronic elements. The electronic elements mounted on the printed circuit board may be assembled to pads arranged in area array on the printed circuit board through solder balls, and electrically connected to each other through conductive vias (vertical electrical media) and conductive traces (horizontal electrical media) inside the printed circuit board.

### SUMMARY OF THE INVENTION

The invention provides an electronic assembly, wherein a printed circuit board thereof provides a flexible pad layout.

The invention provides a printed circuit board for providing a flexible pad layout.

An electronic assembly of the invention includes a printed circuit board, a first electronic package, and a second electronic package. The printed circuit board has a first surface, a second surface opposite to the first surface, a plurality of first conductive pads, a plurality of second conductive pads, a plurality of conductive vias, and a plurality of conductive traces. The conductive vias are vertically disposed in the printed circuit board. The conductive traces are horizontally disposed in the printed circuit board. The first conductive pads are arranged in area array on the first surface. The first conductive pads include a plurality of first signal pads, at least one first signal adjustment pad, and at least one first grounding pad. The second conductive pads are arranged in area array on the second surface. The second conductive pads include a plurality of second signal pads and at least one second signal internal pad. An orthographic projection of the at least one first grounding pad on the first surface and an orthographic projection of the at least one second signal internal pad on the first surface are overlapped with each other. The at least one second signal internal pad is electrically connected to the at least one first signal adjustment pad through the corresponding conductive via, the corresponding conductive trace, and another corresponding conductive via. The at least one first grounding pad is electrically connected to a first landing portion of a first grounding plane in the printed circuit board through the corresponding conductive via. The first electronic package is mounted to the first surface of the printed circuit board and electrically connected to the first conductive pads of the first surface of the printed circuit board. The second electronic package is mounted to the second surface of the printed circuit board and electrically connected to the second conductive pads of the second surface of the printed circuit board.

A printed circuit board of the invention has a first surface and a second surface opposite to the first surface. The printed circuit board includes a plurality of first conductive pads, a plurality of second conductive pads, a plurality of conductive vias, and a plurality of conductive traces. The first conductive pads are arranged in area array on the first surface. The first conductive pads include a plurality of first signal pads, at least one first signal adjustment pad, and at least one first grounding pad. The second conductive pads are arranged in area array on the second surface. The second conductive pads include a plurality of second signal pads and at least one second signal internal pad. An orthographic projection of the at least one first grounding pad on the first surface and an orthographic projection of the at least one second signal internal pad on the first surface are overlapped with each other. The conductive vias are vertically disposed in the printed circuit board. The conductive traces are horizontally disposed in the printed circuit board. The at least one second signal internal pad is electrically connected to the at least one first signal adjustment pad through at least one of the conductive vias and at least one of the conductive traces, and the at least one first grounding pad is electrically connected to a first landing portion of a first grounding plane in the printed circuit board through the corresponding conductive via.

Based on the above, in the invention, the signal pad on the second surface of the printed circuit board is extended to a position outside the orthographic projection on the first surface of the printed circuit board through the conductive vias and the conductive traces in the printed circuit board to dispose another signal pad. Furthermore, the ground pad is disposed at the position of the orthographic projection of the signal pad on the first surface of the printed circuit board to serve as electrical reference and electrical isolation for the signal pad on the first surface of the printed circuit board.

### BRIEF DESCRIPTION OF THE DRAWINGS

FIG. 1A is a schematic view of an electronic assembly of an embodiment of the invention.

FIG. 1B is a partially enlarged view of FIG. 1A.

FIG. 2A is a schematic top view of a portion of a first conductive pad layout of the printed circuit board of FIG. 1A.

FIG. 2B is a schematic top view of a portion of the second conductive pad layout of the printed circuit board of FIG. 1A.

FIG. 3A is a schematic perspective view of the connection relationship of some pads of FIG. 2A and FIG. 2B.

FIG. 3B is a schematic side view of the connection relationship of some pads of FIG. 3A.

FIG. 4A is a schematic perspective view of the connection relationship of some pads of a printed circuit board of an electronic assembly of another embodiment of the invention.

FIG. 4B is a schematic side view of the connection relationship of some pads of FIG. 4A.

### DESCRIPTION OF THE EMBODIMENTS

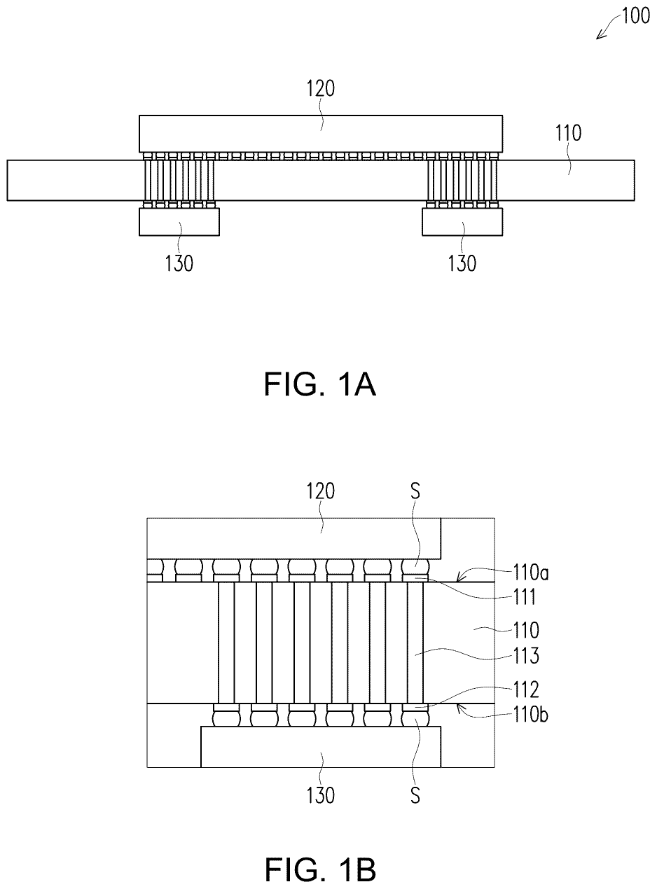

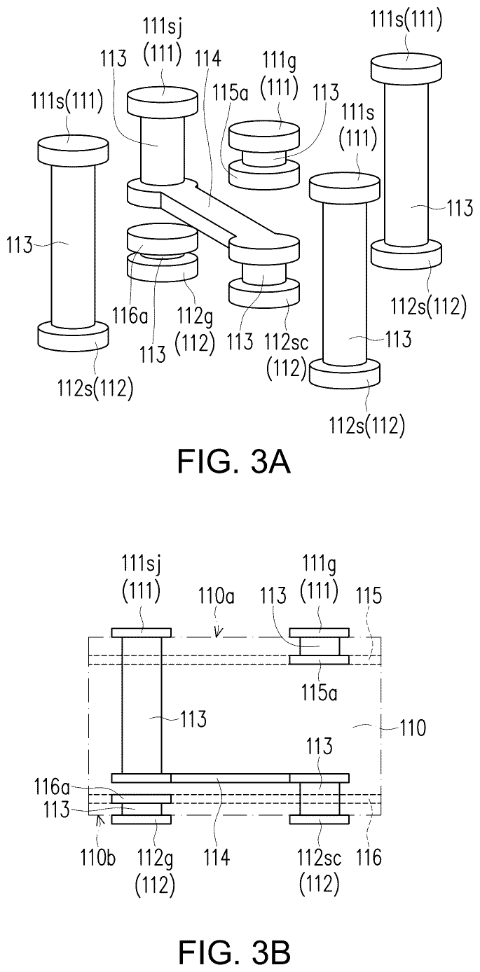

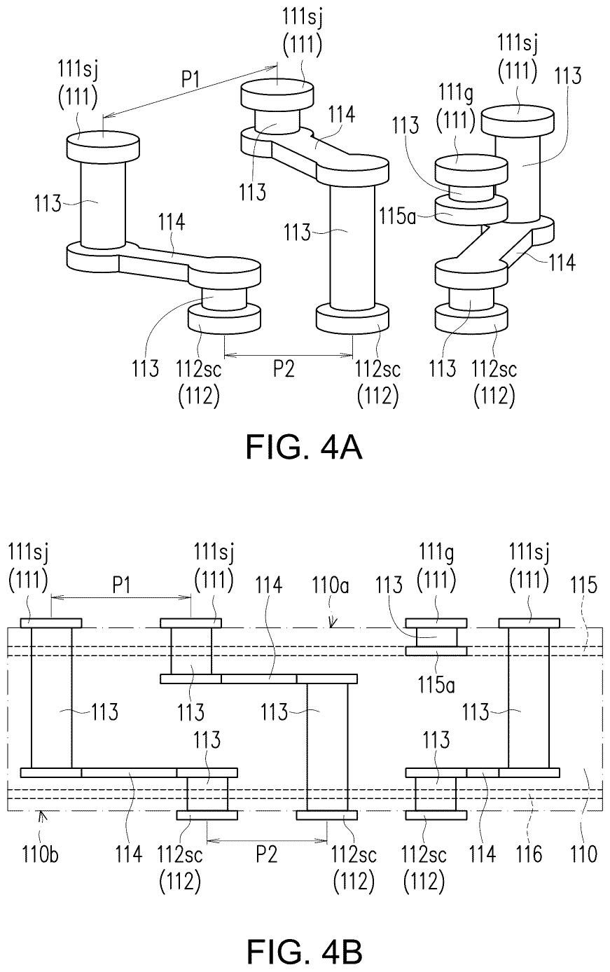

Referring to FIG. 1A and FIG. 1B, in the present embodiment, an electronic assembly 100 includes a printed circuit board 110. The printed circuit board 110 has a first surface 110a, a second surface 110b opposite to the first surface 110a, a plurality of first conductive pads 111, a plurality of second conductive pads 112, a plurality of conductive vias 113, and a plurality of conductive traces 114 (see FIG. 3A, FIG. 3B, FIG. 4A, and FIG. 4B). The first conductive pads 111 are arranged in area array on the first surface 110a. The second conductive pads 112 are arranged in area array on the second surface 110b. The conductive vias 113 are vertically disposed in the printed circuit board 110. As shown of FIG. 3A, FIG. 3B, FIG. 4A, and FIG. 4B, the conductive traces 114 are horizontally disposed in the printed circuit board 110.

In the present embodiment, the electronic assembly 100 further includes a first electronic package 120 and one or a plurality of second electronic packages 130. The first electronic package 120 is mounted to the first surface 110a of the printed circuit board 110 and electrically connected to the first conductive pads 111 of the first surface 110a of the printed circuit board 110. The second electronic package 130 is mounted to the second surface 110b of the printed circuit board 110 and electrically connected to the second conductive pads 112 of the second surface 110b of the printed circuit board 110. For example, the first electronic package 120 may be mounted to the first conductive pads 111 of the first surface 110a of the printed circuit board 110 through solder balls S. The second electronic package 130 may be mounted to the second conductive pads 112 of the second surface 110b of the printed circuit board 110 through the solder balls S.

In the present embodiment, the orthographic projection of the first electronic package 120 on the first surface 110a and the orthographic projection of the second electronic package 130 on the first surface 110a may be overlapped with each other. In addition, the orthographic projection of the second electronic package 130 on the first surface 110a falls in the region of the orthographic projection of the first electronic package 120 on the first surface 110a, i.e., the size of the second electronic package 130 is less than the size of the first electronic package 120. In an embodiment, in the case that there is a plurality of the second electronic package 130, the orthographic projection of each of the second electronic packages 130 on the first surface 110a falls in the region of the orthographic projection of the first electronic package 120 on the first surface 110a. In addition, the first electronic package 120 may be a processor chip package of a larger size, and the second electronic package 130 may be a memory chip package of a smaller size, but it is not limited thereto.

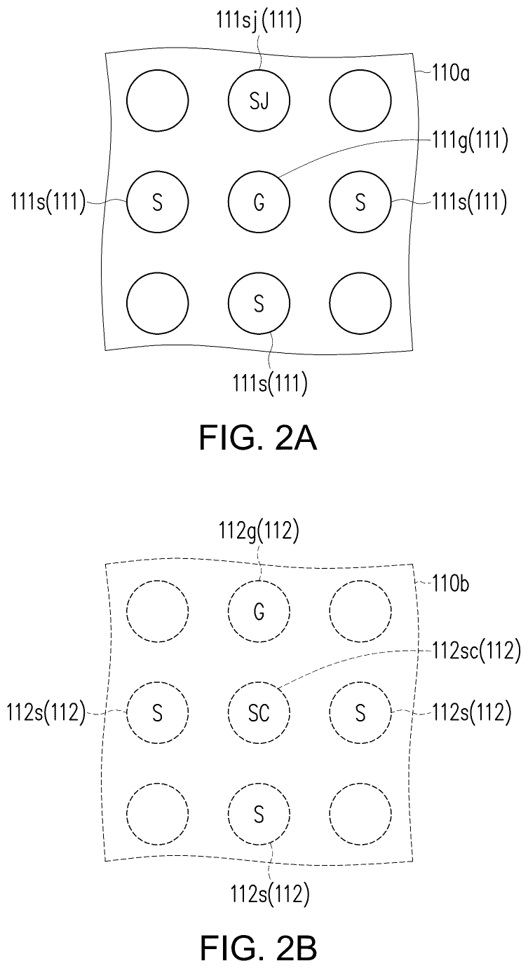

Referring to FIG. 1A, FIG. 1B, FIG. 2A, FIG. 2B, FIG. 3A and FIG. 3B, the first conductive pads 111 include a plurality of first signal pads 111s, at least one first signal adjustment pad 111sj, and at least one first ground pad 111g, wherein at least one of the first signal pads 111s and the first signal adjustment pad 111sj is located around the first ground pad 111g. In the present embodiment, there are a total of three first signal pads 111s and one first signal adjustment pad 111sj located around the first ground pad 111g. In the present embodiment, the first signal pads 111s, the first signal adjustment pad 111sj, and the at least one first ground pad 111g are used for signal transmission between the first electronic package 120 and the second electronic package 130.

The second conductive pads 112 include a plurality of second signal pads 112s, at least one second signal internal pad 112sc, and at least one second ground pad 112g, wherein at least one second signal pad 112s and one second ground pad 112g are disposed around one second signal internal pad 112sc. Here, the second signal internal pad 112sc refers to that there are more second signal pads 112s around the second signal internal pad 112sc than around other second signal pad 112s. In the present embodiment, three second signal pads 112s and one second ground pad 112g are disposed around the second signal internal pad 112sc. In the present embodiment, the second signal pads 112s, the second signal internal pads 112sc, and the at least one second ground pad 112g are used for signal transmission between the first electronic package 120 and the second electronic package 130. Specifically, the total number of the second signal pads 112s, the second signal internal pad 112sc, and the second ground pad 112g is equal to the total number of the first signal pads 111s, the first signal adjustment pad 111sj, and the first ground pad 111g, and the second signal internal pad 112sc and the first signal adjustment pad 111sj are electrically connected to each other.

In the present embodiment, the first ground pad 111g is disposed in an inner region enclosed by the first signal pads 111s and the first signal adjustment pad 111sj on the first surface 110a. The first ground pad 111g may separate the first signal pads 111s and the first signal adjustment pad 111sj from each other, thus providing to isolate signals. Moreover, there are the plurality of second signal pads 112s and the second ground pad 112g around the second signal internal pad 112sc on the second surface 110b. It is particularly noted that since the second surface 110b of the printed circuit board 110 may accommodate a larger region of electronic packages, when a plurality of electronic packages are disposed, the second electronic package 130 is less affected to signal interference from other adjacent electronic packages. However, the first signal pads 111s on the first surface 110a of the printed circuit board 110 are mostly concentrated below the projection of the first electronic package 120, resulting in relatively limited space. Therefore, when the signal of the second electronic package 130 is transmitted from the second surface 110b to the first surface 110a, a ground pad (e.g., the first ground pad 111g) needs to be placed at an appropriate position on the first surface 110a for isolation to maintain the quality of signal transmission. Moreover, the orthographic projection of the first ground pad 111g of FIG. 2A and FIG. 2B on the first surface 110a and the orthographic projection of the second signal internal pad 112sc on the first surface 110a are overlapped with each other, which is described in detail later.

Referring to FIG. 3A and FIG. 3B, the second signal internal pad 112sc on the second surface 110b is electrically connected to the first signal adjustment pad 111sj on the first surface 110a through one or a plurality of conductive vias 113 and one or a plurality of conductive traces 114, wherein the conductive via 113 and the conductive trace 114 are located in the printed circuit board 110. The first ground pad 111g is electrically connected to a first landing portion 115a of a first ground plane 115 in the printed circuit board 110 through the corresponding conductive via 113. The first landing portion 115a and the conductive trace 114 are located at different layers, wherein the conductive trace 114 is electrically connected to the second signal internal pad 112sc. Therefore, the signal path may be shifted from the original position of the orthographic projection of the second signal internal pad 112sc on the second surface 110b to the position of the orthographic projection of the first signal adjustment pad 111sj on the first surface 110a. Furthermore, the position of the orthographic projection of the second signal internal pad 112sc on the first surface 110a is exactly the position of the orthographic projection of the first ground pad 111g on the first surface 110a, but the second signal internal pad 112sc and the first ground pad 111g are structurally separated and not connected to each other.

Referring to FIG. 3A and FIG. 3B, in the present embodiment, the second conductive pads 112 may further include a second ground pad 112g. The second ground pad 112g is electrically connected to a second landing portion 116a of a second ground plane 116 in the printed circuit board 110 through the corresponding conductive via 113, and the orthographic projection of the second ground pad 112g on the second surface 110b and the orthographic projection of the first signal adjustment pad 111sj on the second surface 110b are overlapped with each other. In the present embodiment, the second landing portion 116a and the conductive trace 114 are located at different layers, wherein the conductive trace 114 is electrically connected to the second signal internal pad 112sc. In addition, the first signal adjustment pad 111sj and the second ground pad 112g are structurally separated and not connected to each other. In this configuration, the positions of the orthographic projections of the second signal internal pad 112sc and the second ground pad 112g on the first surface 110a, when interchanged, are exactly the positions of the orthographic projections of the first signal adjustment pad 111sj and the first ground pad 111g on the first surface 110a. Therefore, the central position of the second ground pad 112g on the second surface 110b is changed to the sounding position of the first signal adjustment pad 111sj on the first surface 110a by the conductive via 113 and the conductive trace 114. In this way, since there is a ground pad at the middle region of the plurality of signal pads of the first surface 110a, a better isolation effect is achieved.

Based on the above, the second signal pads 112s around the second signal internal pad 112sc on the second surface 110b may be directly electrically connected to the corresponding first signal pads 111s on the first surface 110a through the conductive vias 113 passing through the printed circuit board 110. The second signal internal pad 112sc on the second surface 110b and surrounded by the second signal pads 112s may be indirectly electrically connected to the first signal adjustment pad 111sj on the first surface 110a through one or a plurality of conductive vias 113 and one or a plurality of conductive traces 114. In addition, the second signal internal pad 112sc and the second ground pad 112g on the second surface 110b may interchange their positions on the first surface 110a. Moreover, in FIG. 3A and FIG. 3B, the orthographic projections of the peripheral second signal pads 112s, the second signal internal pad 112sc, and the second ground pad 112g on the second surface 110b and the orthographic projections of the peripheral first signal pads 111s, the first ground pad 111g, and the first signal adjustment pad 111sj on the second surface 110b are overlapped with each other.

Referring to FIG. 2A and FIG. 2B, when the second signal internal pad 112sc of FIG. 2B is closer to the second signal pad 112s, the signal transmission is from the second signal internal pad 112sc to the first signal adjustment pad 111sj through the conductive vias 113 and the conductive trace 114 in the printed circuit board 110 of FIG. 3A and FIG. 3B, and the positions of the orthographic projections of the second ground pad 112g and the first signal adjustment pad 111sj on the first surface 110a are not overlapped each other. Therefore, there is the first ground pad 111g at the central region, the first signal adjustment pad 111sj is far away from the first signal pads 111s, and the signal interference can be reduced.

Referring to FIG. 4A and FIG. 4B, compared to the embodiment of FIG. 1B, in the present embodiment, the first conductive pads 111 include a plurality of first signal adjustment pads 111sj, and the second conductive pads 112 include a plurality of second signal internal pads 112sc. Each of the second signal internal pads 112sc is also electrically connected to the corresponding first signal adjustment pad 111sj through the corresponding conductive via 113, the corresponding conductive trace 114, and another corresponding conductive via 113. In addition, a first pitch P1 between two adjacent first signal adjustment pads 111sj is greater than a second pitch P2 between two adjacent second signal internal pads 112sc. Therefore, in the same region, the arrangement density of the first signal adjustment pads 111sj is less than the arrangement density of the second signal internal pads 112sc. Therefore, compared to FIG. 3A and FIG. 3B, in addition to the electrical isolation effect produced by the first ground pad 111g on the first surface 110a, the first pitch P1 between the first signal adjustment pads 111sj on the first surface 110a is larger, which may also create a better spatial isolation effect than that of FIG. 3A and FIG. 3B to avoid signal interference.

In addition, the first conductive pads 111 further include a first ground pad 111g. The first ground pad 111g is electrically connected to a first landing portion 115a of a first ground plane 115 in the printed circuit board 110 through the corresponding conductive via 113. The first landing portion 115a and the conductive trace 114 are located at different layers, wherein the conductive trace 114 is electrically connected to the second signal internal pads 112sc. In some embodiments, the position of the orthographic projection of the second signal internal pads 112sc on the first surface 110a is exactly the position of the orthographic projection of the first ground pad 111g on the first surface 110a. However, the second signal internal pads 112sc and the first ground pad 111g are structurally separated and not connected to each other.

Based on the above, in the invention, the signal pad on the second surface of the printed circuit board is extended to a position outside the orthographic projection on the first surface of the printed circuit board through the conductive vias and the conductive traces in the printed circuit board to dispose another signal pad. Furthermore, the ground pad is disposed at the position of the orthographic projection of the signal pad on the first surface of the printed circuit board to serve as electrical reference and electrical isolation for the signal pad on the first surface of the printed circuit board.

Furthermore, the plurality of signal pads are adjacently arranged on a surface of the printed circuit board, so the corresponding signal pads of the adjacently arranged signal pads on the other surface of the printed circuit board are not crowded, and there are also ground pads to separate the signal pads.

In addition, the density of pads arranged on a surface of the printed circuit board may be different from the density of pads arranged on another surface of the printed circuit board, so as to reduce signal interference through the pads with lower density.

What is claimed is:

1. An electronic assembly, comprising:
a printed circuit board has a first surface, a second surface opposite to the first surface, a plurality of first conductive pads, a plurality of second conductive pads, a plurality of conductive vias, and a plurality of conductive traces, wherein
the conductive vias are vertically disposed in the printed circuit board,
the conductive traces are horizontally disposed in the printed circuit board,
the first conductive pads are arranged in area array on the first surface, the first conductive pads comprise a plurality of first signal pads, at least one first signal adjustment pad, and at least one first ground pad,
the second conductive pads are arranged in area array on the second surface, the second conductive pads comprise a plurality of second signal pads and at least one second signal internal pad,
an orthographic projection of the at least one first ground pad on the first surface and an orthographic projection of the at least one second signal internal pad on the first surface are overlapped with each other,
the at least one second signal internal pad is electrically connected to the at least one first signal adjustment pad through at least one of the conductive vias and at least one of the conductive traces, and
the at least one first ground pad is electrically connected to a first landing portion of a first ground plane in the printed circuit board through the corresponding conductive via;
a first electronic package mounted to the first surface of the printed circuit board and electrically connected to the first conductive pads of the first surface of the printed circuit board; and
a second electronic package mounted to the second surface of the printed circuit board and electrically connected to the second conductive pads of the second surface of the printed circuit board.

2. The electronic assembly of claim 1, wherein the second conductive pads further comprise at least one second ground pad, the at least one second ground pad is electrically connected to a second landing portion of a second ground plane in the printed circuit board through the corresponding conductive via, and an orthographic projection of the at least one second ground pad on the second surface and an orthographic projection of the at least one first signal adjustment pad on the second surface are overlapped with each other.

3. The electronic assembly of claim 2, wherein at least one of the second signal pads and one second ground pad are disposed around the at least one second signal internal pad.

4. The electronic assembly of claim 2, wherein three of the second signal pads and one second ground pad are disposed around the at least one second signal internal pad.

5. The electronic assembly of claim 2, wherein a total number of the second signal pads, the at least one second signal internal pad, and the at least one second ground pad is equal to a total number of the first signal pads, the at least one first signal adjustment pad, and the at least one first ground pad.

6. The electronic assembly of claim 1, wherein at least one of the first signal pads and the at least one first signal adjustment pad are located around the at least one first ground pad.

7. The electronic assembly of claim 1, wherein three of the first signal pads and the at least one first signal adjustment pad are located around the at least one first ground pad.

8. The electronic assembly of claim 1, wherein the second signal pads around the at least one second signal internal pad are directly electrically connected to the corresponding first signal pads through the conductive vias passing through the printed circuit board.

9. The electronic assembly of claim 1, wherein a number of the at least one first signal adjustment pad is a plurality, a number of the at least one second signal internal pad is a plurality, and in a same region, an arrangement density of the first signal pads is less than an arrangement density of the second signal pads.

10. The electronic assembly of claim 9, wherein a pitch between two adjacent first signal adjustment pads is greater than a pitch between two adjacent second signal internal pads.

11. The electronic assembly of claim 1, wherein an orthographic projection of the second electronic package on the first surface falls in a region of an orthographic projection of the first electronic package on the first surface.

12. The electronic assembly of claim 1, wherein a number of the second electronic package is a plurality, and an orthographic projection of each of the second electronic packages on the first surface falls in a region of an orthographic projection of the first electronic package on the first surface.

13. A printed circuit board, having a first surface and a second surface opposite to the first surface, the printed circuit board comprising:
a plurality of first conductive pads arranged in area array on the first surface, wherein the first conductive pads comprise a first signal pad, at least one first signal adjustment pad, and at least one first ground pad;
a plurality of second conductive pads arranged in area array on the second surface, wherein the second conductive pads comprise a second signal pad and at least one second signal internal pad, and an orthographic projection of the at least one first ground pad on the first surface and an orthographic projection of the at least one second signal internal pad on the first surface are overlapped with each other;
a plurality of conductive vias vertically disposed in the printed circuit board; and
a plurality of conductive traces horizontally disposed in the printed circuit board, wherein the at least one second signal internal pad is electrically connected to the at least one first signal adjustment pad through at least one of the conductive vias and at least one of the conductive traces, and the at least one first ground pad is electrically connected to a first landing portion of a first ground plane in the printed circuit board through the corresponding conductive via.

14. The printed circuit board of claim 13, wherein the second conductive pads further comprise at least one second ground pad, the at least one second ground pad is electrically connected to a second landing portion of a second ground plane in the printed circuit board through the corresponding conductive via, and an orthographic projection of the at least one second ground pad on the second surface and an orthographic projection of the at least one first signal adjustment pad on the second surface are overlapped with each other.

15. The printed circuit board of claim 14, wherein three of the second signal pads and one second ground pad are disposed around the at least one second signal inner pad.

16. The printed circuit board of claim 14, wherein a total number of the second signal pads, the at least one second signal internal pad, and the at least one second ground pad is equal to a total number of the first signal pads, the at least one first signal adjustment pad, and the at least one first ground pad.

17. The printed circuit board of claim 13, wherein three of the first signal pads and the at least one first signal adjustment pad are located around the at least one first ground pad.

18. The printed circuit board of claim 13, wherein the second signal pads around the at least one second signal internal pad are directly and electrically connected to the corresponding first signal pads through the conductive vias passing through the printed circuit board.

19. The printed circuit board of claim 13, wherein a number of the at least one first signal adjustment pad is a plurality, a number of the at least one second signal internal pad is a plurality, and in a same region, an arrangement density of the first signal pads is less than an arrangement density of the second signal pads.

20. The printed circuit board of claim 19, wherein a pitch between two adjacent first signal adjustment pads is greater than a pitch between two adjacent second signal internal pads.
